(19) United States
(12) Patent Application Publication
(10) Pub. No.: US 2023/0343620 A1
(43) Pub. Date: Oct. 26, 2023

(54) SYSTEM AND METHOD FOR CONVEYING AND INSPECTING SEMICONDUCTOR PACKAGE

(71) Applicant: VITROX TECHNOLOGIES SDN BHD, Bandar Cassia (MY)

(72) Inventors: Juson Dun Lee KHAW, Bukit Mertajam (MY); Yoong Fatt CHIANG, BAYAN LEPAS (MY); Dennis Yong Sheng ONG, Georgetown (MY); Megat Abdullah BIN MEGAT MOHD AZLAN, Sungai Petani (MY); Tek Pei KANG, Bayan Lepas (MY); Jerrod Sheng Chun FOO, Ipoh (MY); Kai Wen TEE, Simpang Ampat (MY); Jia Xun TAI, KEDAH DARUL AMAN (MY); Kek Keong KIM, Permatang (MY); Yik Loong KOK, Gelugor (MY); Siang Loong ONG, Bayan Lepas (MY); Ker Ming KHOR, Bayan Lepas (MY); Chin Lee YEAP, Butterworth (MY); Chuzen LEE, Sungai Ara (MY)

(21) Appl. No.: 18/045,806

(22) Filed: Oct. 11, 2022

(30) Foreign Application Priority Data
Apr. 20, 2022 (MY) PI2022002024

(51) Int. Cl. H01L 21/67; H01L 21/677

(52) U.S. Cl. CPC H01L 21/67288; H01L 21/67706; H01L 21/67721

(57) ABSTRACT

Embodiments of the present invention generally relate to the field of semiconductor, in particular to a system and method for conveying and inspecting semiconductor package. More particularly, the present invention relates to the post-seal inspection system and method that performs automatic conveyance of semiconductor package for inspection process.

### TECHNICAL FIELD OF THE INVENTION

Embodiments of the present invention generally relate to the field of semiconductor, in particular to a system and method for conveying and inspecting semiconductor package. More particularly, the present invention relates to the post-seal inspection system and method that performs automatic conveyance of the semiconductor package for inspection process.

### BACKGROUND OF THE INVENTION

Electronic components, such as semiconductor devices, components, parts, units, chips, integrated circuits and etc, are subjected to the manufacturing process and then tested for appearance, electrical characteristics and vision inspection, and then individually packaged and shipped to the outside. In this case, a packaging container in which electronic components are individually packaged is used to prevent physical damage such as breakage of an electronic component from an external impact, and to prevent electrical damage due to static electricity or the like.

The packaging container may take in the form of carrier tape, wherein the electronic component is packaged into the carrier tape, which is mounted at regular intervals on the carrier tape and attached or sealed with a transparent cover tape and then shipped on a reel. Before the sealed carrier tape is shipped, some of the plurality of electronic components to be mounted may be defective, so it is necessary to inspect whether the defect is defective.

Conventional carrier tape inspection device for inspecting such a carrier tape performs a process of inspecting the electronic component in the middle while unwinding the carrier tape wound on a supply reel on one side and winding the unwinding tape on another take-up reel on the other side after inspecting the electronic component in the middle. However, such conventional inspection process requires additional work or manual labour from the operators to manually attach the leading end of the carrier tape from the supply reel to the tape guiding track or to manually attach the leading end of the carrier tape to the dummy reel after having inspected. When the operator has to do such attachments, the inspection process is stopped, conveyance speed of carrier tape is limited at a predetermined speed, and the packaging of inspected carrier tape onto take-up reel is also impacted, hence reducing the productivity rate.

On the other hand, since the replacement of supply reel and dummy reel after the carrier tape has been inspected is unavoidable in affecting the productivity rate, such manual attaching work has further delayed the entire process, which relatively requires longer working time for one reel inspection.

Therefore, such manual attaching work has led to low productivity rate, the labour is wasted and the convenience of the work is poor.

Additionally, the conventional inspection system for carrier tape requires an additional dummy reel or packaging reel on the other side of the system to collect or wind the inspected carrier tape. The supply reel which is empty by now requires additional unloading works, processing works such as re-labelling, remarking, reel inspection before winding subsequent carrier tapes, and winding of carrier tape. These processes have again, delayed the productivity and led to poor inventory management. Moreover, the replacement of dummy reel is necessary in the conventional inspection system because the width of the dummy reel is not adjustable and only compatible or suitable to a fixed size of carrier tape, thereby causing inconvenience when there are various sizes of carrier tape to be inspected.

Hence, it would be advantageous to alleviate the shortcomings by having the following disclosure therein, particularly having a system and method for conveying and inspecting carrier tape for inspection, that is capable of inspecting and detecting the defect on the electronic components contained within the carrier tape, inspecting the quality of the sealing line of cover tape after the components have been sealed with the cover tape in the carrier tape and detecting the defect on the carrier tape, whereby the conveyance of carrier tape within the system is performed automatically without the need of additional manual work.

### SUMMARY OF THE INVENTION

Accordingly, it is the primary aim of the present invention to provide a system and method for conveying and inspecting at least a semiconductor package.

It is yet another objective of the present invention to provide a post-seal inspection system and method of inspecting and detecting the defect on the electronic components contained within a carrier tape.

It is yet another objective of the present invention to provide a post-seal inspection system and method of inspecting and detecting the quality of the sealing line of cover tape after the components have been sealed with the cover tape in the carrier tape, or the seal between the cover tape and carrier tape.

It is yet another objective of the present invention to provide a post-seal inspection system and method of inspecting and detecting the defect on the carrier tape.

It is yet another objective of the present invention to provide a post-seal inspection system and method that is capable to guide or attach the carrier tape from a reel module to inspection station automatically without the need of manual attaching work.

It is yet another objective of the present invention to provide a system and method relating to an automated conveyance of carrier tape without the need of manual attaching work.

It is yet another objective of the present invention to provide a post-seal inspection system and method wherein no take-up reel is required as the carrier tape loaded out from the supply reel will be reloaded back to the supply reel after having inspected.

It is yet another objective of the present invention to provide a post-seal inspection system and method that provides multiple tracks of inspection line.

It is yet another objective of the present invention to provide a system and method having the supply reel as the take-up reel or packaging reel wherein the carrier tape is wound back to the supply reel.

Additional objects of the invention will become apparent with an understanding of the following detailed description of the invention or upon employment of the invention in actual practice.

According to the preferred embodiment of the present invention the following is provided:

A system for conveying and inspecting semiconductor package comprising:
at least a feeder reel module located on one side of the system for mounting at least a supply reel wound with the semiconductor package;
at least a carrier tape rail track module for receiving the semiconductor package dispensed from the feeder reel module and conveying the semiconductor package;
at least an inspection module disposed at a position proximally to the carrier tape rail track module;
characterized in that
said system further comprising at least a first arm module located on another side of the system for winding the semiconductor package conveyed from the carrier tape rail track module and rewinding the wound semiconductor package to the inspection module for inspection before the inspected semiconductor package winds back into feeder reel module, wherein said winding and rewinding process are performed automatically using an automation means.

In another embodiment of the present invention the following is provided:

A method for conveying and inspecting semiconductor package (1300), comprising the steps of:
(i) dispensing semiconductor package from a supply reel (R) (1310);
(ii) conveying the semiconductor package from the supply reel (R) onto a rail track (51) (1330);
(iii) conveying the semiconductor package from the rail track (51) to a temporary take-up reel (71) (1350);
characterized in that the method (1300) further comprising the step of
(iv) winding the semiconductor package into the temporary take-up reel (71) (1370);
(v) re-winding the wound semiconductor package from the temporary take-up reel (71) to back to the supply reel (R) through the rail track (51) (1390); wherein the semiconductor package is subjected to inspecting process by at least an inspection module (11) during the rewinding process.

### BRIEF DESCRIPTION OF THE DRAWINGS

Other aspect of the present invention and their advantages will be discerned after studying the Detailed Description in conjunction with the accompanying drawings in which:

FIGS. 1-A and 1-B illustrate the exemplary perspective view and front view of the system for conveying and inspecting carrier tape according to the preferred embodiment of the present invention.

FIGS. 2-A and 2-B illustrate an exemplary pathway of the carrier tape from one side of the system to another side of the system.

FIGS. 3-A to 3-D illustrate an exemplary first arm module of the system in perspective view, front view and top view.

FIGS. 4-A to 4-D illustrate one section of the first arm module of the system in front view, perspective, exploded view and cross-sectional view respectively.

FIG. 5 illustrates an exemplary example of the leading end of carrier tape.

FIGS. 6-A to 6-B illustrate another section of the first arm module of the system in perspective view and exploded view respectively.

FIGS. 7-A to 7-B illustrate another section of the first arm module of the system in front view and perspective view respectively.

FIGS. 8-A to 8-B illustrate another section of the first arm module of the system in perspective views.

FIG. 9 illustrate an exemplary inspection module the system.

FIGS. 10-A to 10-D illustrate an exemplary operation of the system according to the preferred embodiment of present invention.

FIG. 11 illustrates another embodiment of the present invention.

FIG. 12 illustrates another embodiment of the present invention.

FIG. 13 illustrates an exemplary method flow according to present invention.

### DETAILED DESCRIPTION OF THE DRAWINGS

In the following detailed description, numerous specific details are set forth in order to provide a thorough understanding of the invention. However, it will be understood by the person having ordinary skill in the art that the invention may be practised without these specific details. In other instances, well known methods, procedures and/or components have not been described in detail so as not to obscure the invention.

The invention will be more clearly understood from the following description of the embodiments thereof, given by way of example only with reference to the accompanying drawings, which are not drawn to scale.

As used in this disclosure and the appended claims herein, the singular forms “a”, “an”, and “the” include plural referents unless the context clearly dictates or denotes otherwise.

Throughout the disclosure and claims of this specification, the word “comprise” and variations of the word, such as “comprising” and “comprises,” means “including but not limited to,” and is not intended to exclude, for example, other components, integers or steps. “Exemplary” means “an example of” and is not intended to convey an indication of a preferred or ideal embodiment, “such as” is not used in a restrictive sense, but for explanatory purposes.

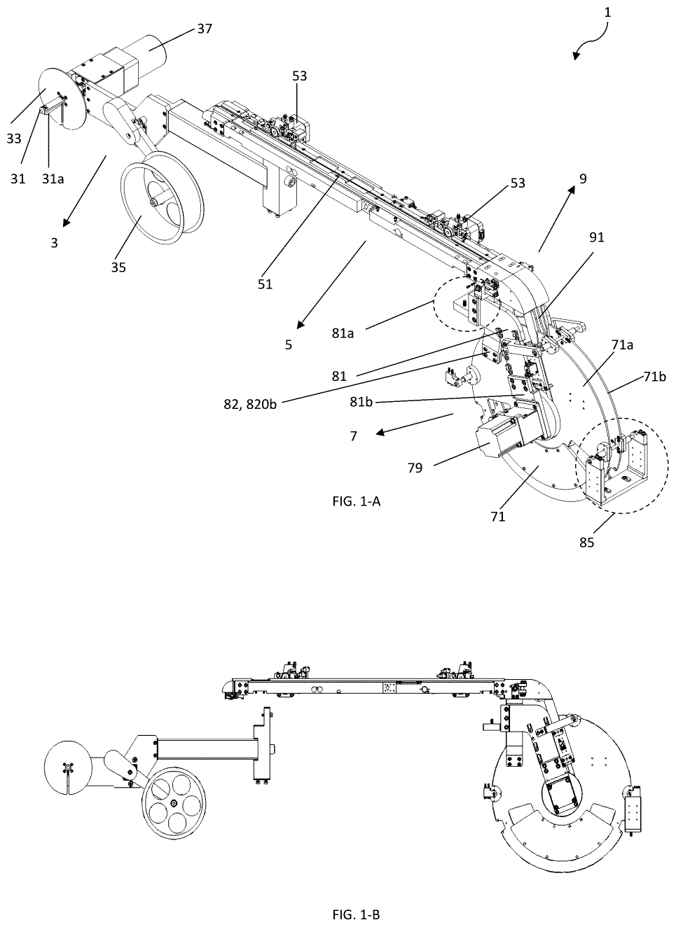

FIGS. 1-A and 1-B show an exemplary perspective view and front view of a system for conveying and inspecting at least a semiconductor package (1) according to the preferred embodiment of the present invention. The term “semiconductor package” mentioned throughout the document is referred to carrier tape, wherein said carrier tape may or may not contain electronic components. Hence, the inspection area of said system (1) includes but not limited to the inspection on the carrier tape (C), the electronic components that are sealed within the carrier tape (if the carrier tape (C) contains electronic components), the cover tape sealing the carrier tape, the sealing between the cover tape and carrier tape or the packaging state of the carrier tape (C) so that corrective measures to be taken before the electronic components are shipped to the ultimate user.

The word “electronic components” mentioned throughout this specification including but not limited to semiconductor devices, components, parts, units, chips, integrated circuits.

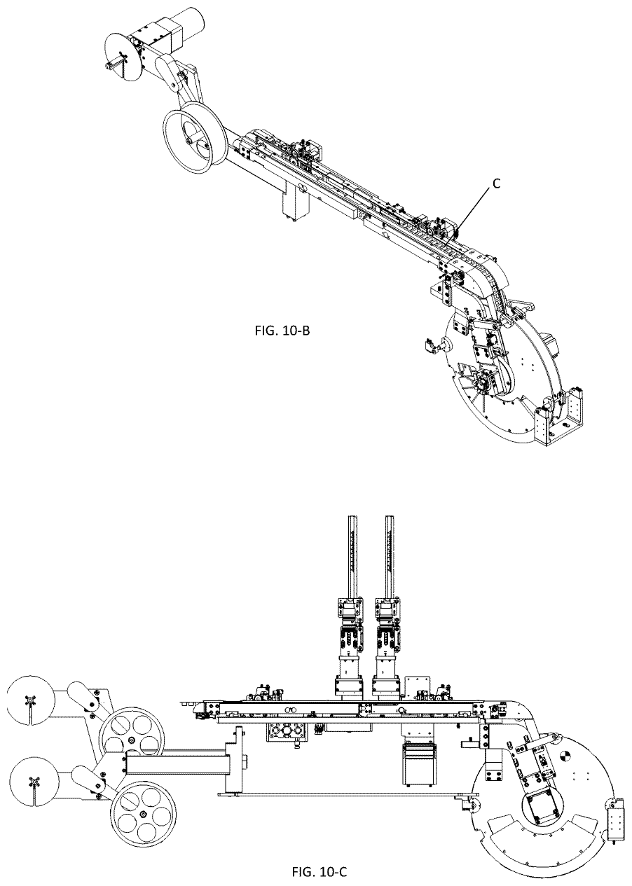

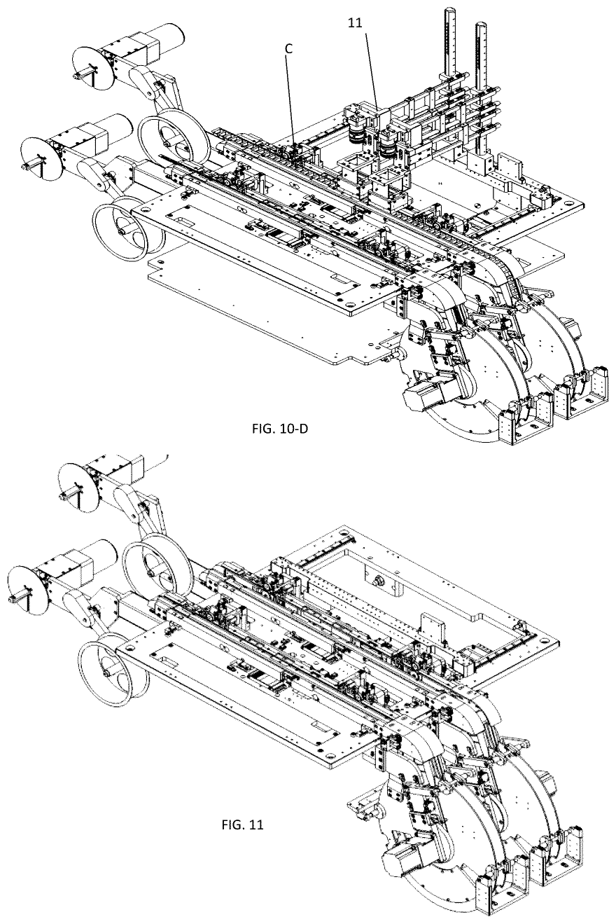

Said system for conveying and inspecting at least a semiconductor package, in particular carrier tape (C) (1) comprising at least a feeder reel module (3), at least a carrier tape rail track module (5), at least a first arm module (7), at least a tape guiding bridge module (9) and at least an inspection module (11) (as shown in FIG. 10-C).

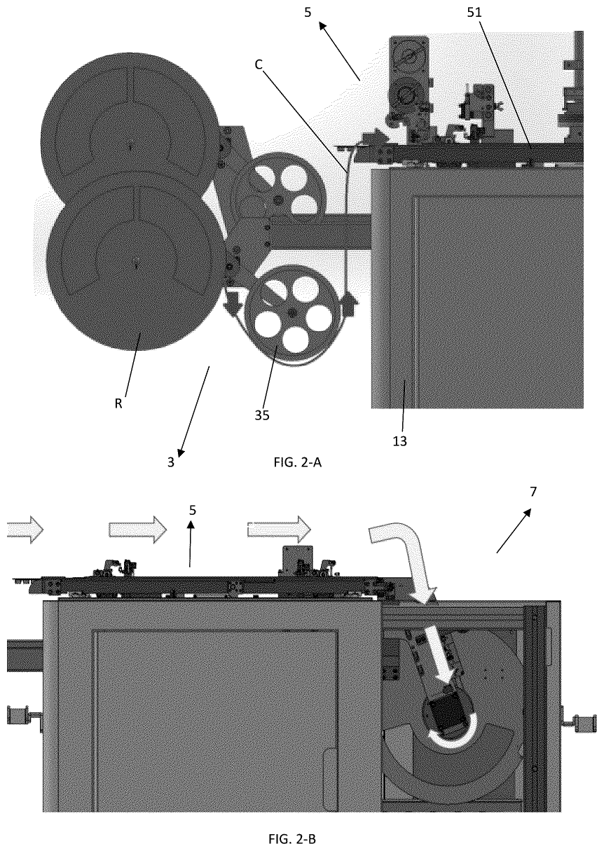

Said feeder reel module (3) of the system (1) is positioned or located on one side of the system (1) for mounting at least a supply reel or input reel (R) wound with semiconductor package, in particular carrier tape (C), wherein the supply reel or input reel (R) is inserted to the spindle or reel shaft (31) of the feeder reel module (3). The carrier tape (C) wound on the supply reel or input reel (R) is preferably, contained with the electronic components. Although it is preferably for said system (1) to convey and inspect the carrier tape (C) containing electronic components, it is also envisaged that the system (1) could be used to convey and inspect empty carrier tape (C) as the system (1) deems fit. The feeder reel module (3) further comprising at least a reel plate (33) coupled with the reel shaft (31) for the placement or loading of at least an input reel or supply reel wound with carrier tape, whereby when the input reel or supply reel (R) is placed into the reel shaft (31) the input reel or supply reel (R) will be secured and hold by the fin (31a) at the reel shaft (31). Particularly, the sprocket hole of the carrier tape engages with the fin (31a) of the reel shaft (31), hence stabling the position of the supply reel or input reel in the reel shaft (31) of the feeder reel module (31). The feeder reel module (3) further comprising at least buffer roller (35) positioned proximally to the reel plate (33) and reel shaft (31) to facilitate the dispensing of carrier tape (C) from the supply reel or input reel (R), in particular for conveying and routing the carrier tape (C) to the carrier tape rail track module (5) in order to maintain the carrier tape (C) in tension during the winding process. The leading end of the carrier tape (C) may be manually routed by the operator or user to the buffer roller (35) and into the carrier tape rail track module (5). FIG. 2-A shows the pathway of the carrier tape (C) from the supply reel or input reel to buffer roller (35) and then to the carrier tape rail track module (5). It is envisaged that the insertion of the carrier tape (C) into the buffer roller (35) and carrier tape rail track module (5) could also be done automatically. It is also contemplated that the buffer roller (35) may be excluded in one embodiment whereby the carrier tape (C) will be manually or automatically inserted into the carrier tape rail track module (5) directly from the supply reel or input reel (R). The feeder reel module (3) further comprising at least a motor assembly (37) coupled at another end of the reel shaft for permitting the rotation motion of the reel shaft (31), enabling the input reel or supply reel (R) to be rotated to wind out or dispense the carrier tape (C).

Said carrier tape rail track module (5) of the system (1) is preferably disposed between the feeder reel module (3) and the first arm module (7), wherein it is configured to convey or transport the carrier tape (C) from one place to another, in particular to receive the carrier tape (C) dispensed or loaded out from the supply reel (R) mounted on the feeder reel module (3) in one embodiment or from the buffer roller (35) in another embodiment, and then to convey the carrier tape (C) to the first arm module (7). Preferably, said carrier tape rail track module (5) comprising a rail track (51), of which is run by pulleys, drive rollers, drums or sprockets (not shown) underlying or beneath the rail track (51), wherein said pulleys, drums or sprockets are powered, hence capable of advancing, moving or pulling said rail track (51) forwardly or rearwardly. Alternatively, said carrier tape rail track module (5) could be a belt conveyor system comprising pulleys with a closed loop of carrying medium whereby the conveyor belt rotates about them, hence advancing or moving the carrier tape (C) forwardly or rearwardly when the carrier tape (C) is received on the rail track. Preferably, said carrier tape rail track module (5) further comprising plurality of sensors (53) along the rail track (51) to detect the presence of carrier tape (C) at the inlet or outlet of the rail track (51) wherein the rail track (51) is actuated or initiated when the leading end of carrier tape (C) is inserted into the rail track (51); to detect the smoothness of carrier tape conveyance on the rail track (51); or to detect the deficiencies of the carrier tape (C) while it is being conveyed on the rail track (51).

In one embodiment of the present invention, the width of the rail track (51) of carrier tape rail track module (5) is adjustable according to the size of the carrier tape (C), wherein the width of the rail track (51) is initially pre-set by operator or user using at least a controller module (15) according to the intended size of carrier tape (C) before the use of the system (1). Alternatively, it is envisaged that the width of the rail track (51) is automatically adjusted to the size of the carrier tape (C) when the incoming carrier tape (C) is received on the rail track (51), hence positioning the carrier tape (C) on the rail track (51) securely.

The first arm module (7) of the system (1) is located on another side of the system (1) for winding the carrier tape into the first arm module (7) after it is dispensed out from the feeder reel module (3) and conveyed from the carrier tape rail track module (5); and then rewinding the wound carrier tape back to the carrier tape rail track module (5) and to the inspection module (11) for inspection before winding back to the supply reel or input reel (R), wherein said winding and rewinding process are performed automatically using an automation means which will be discussed in detail later. FIG. 2-B shows that pathway of the carrier tape (C) from carrier tape rail track module (5) to first arm module (7).

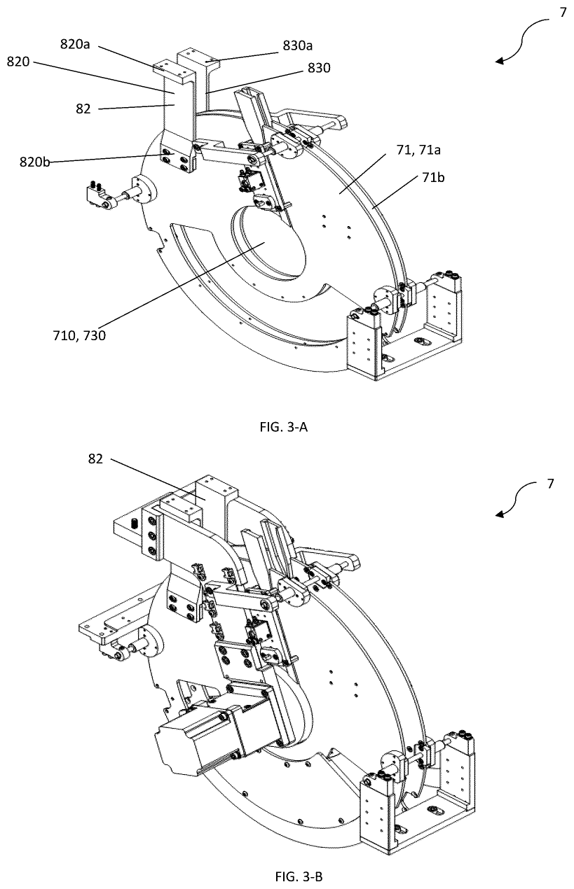

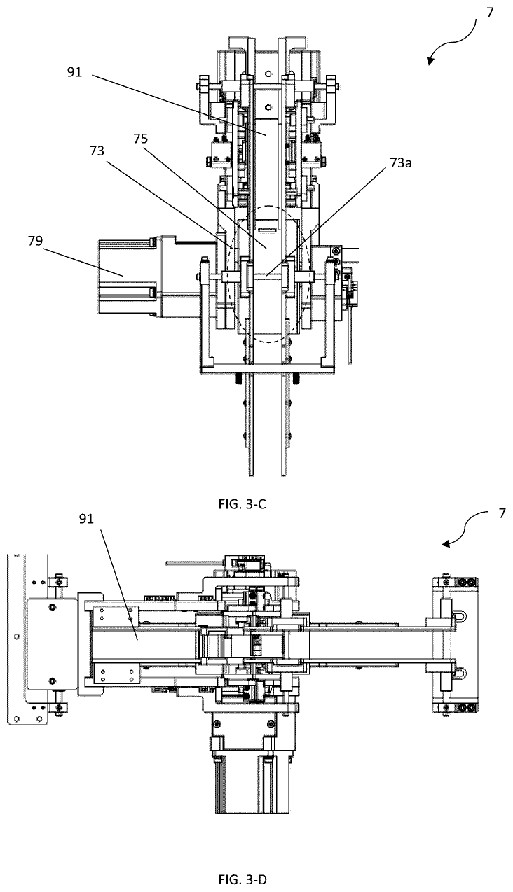

FIGS. 3-A to 3-D show the close-up and detailed views of the first arm module (7). The first arm module (7) of the system (1) comprising at least a temporary take-up reel (71) comprising at least first reel plate (71a) comprising a through hole (710); at least a second reel plate (71b) comprising a through hole (730), wherein said second reel plate (71b) having its through hole (730) facing the through hole (710) of the first reel plate (71a) substantially parallelly; and at least a rotary module (73) disposed between first and second reel plates (71a, 71b).

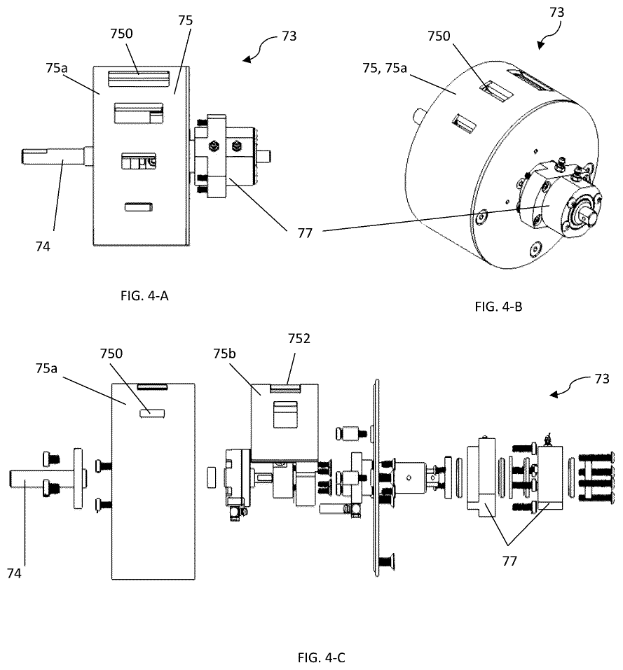

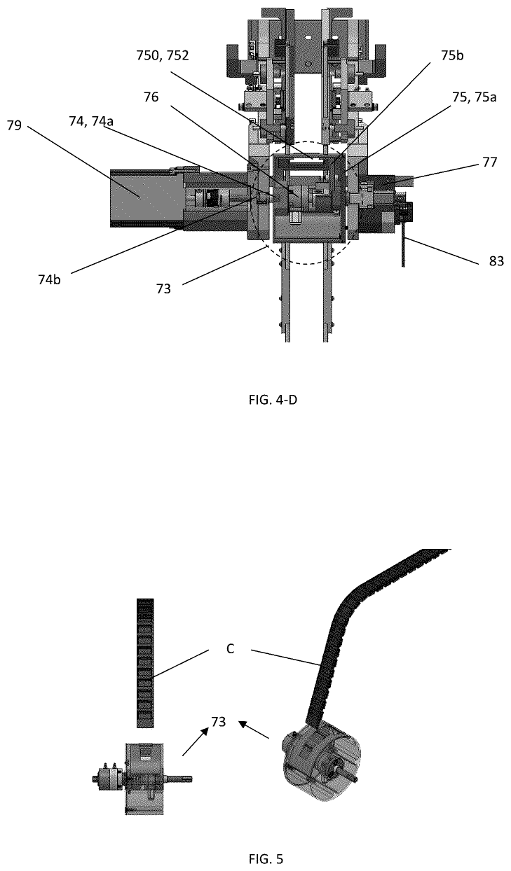

FIGS. 4-A to 4-D show an exemplary embodiment of the rotary module (73) in top view, perspective view, exploded view and cross-sectional view respectively. The rotary module (73) comprising at least a rotary shaft (74) having its one end (74a) coupled with at least a rotary drum (75), wherein said rotary drum (75) comprising a first cylindrical body (75a) comprising at least an insertion slot (750) at its surface or circumference for the insertion of carrier tape (C). The rotary module (73) further comprising at least a concave member (75b) which is defined as a clamper for clamping the leading end of carrier tape (C), comprising at least an insertion slot (752) wherein said concave member (75b) is positioned beneath said first cylindrical body (75a) and is formed with the same radius of curvature with said first cylindrical body (75a), hence having a substantially similar curvature. Alternatively, a second cylindrical body (not shown) may be used whereby it is coaxially surrounded by said first cylindrical body (75a). FIG. 5 shows an example of the leading end of carrier tape before it is inserted into the rotary module (73). The rotary module (73) further comprising at least a rotary cylinder (76) positioned inside the rotary drum (75) and is coupled to the concave member (75b) for actuating the clamping or rotating motion of the concave member (75b). The rotary module (73) further comprising at least an auxiliary rotary module (77) which is a rotary union coupled to another end of rotary drum (75) to provide seal between fluid supply passage (such as pipe or tubing) (not shown) and the rotary cylinder (76) to permit the flow of a fluid into and/or out of the rotary cylinder (76), hence enabling rotary motion of said concave member (75b).

Said first arm module (7) further comprising at least a motor assembly (79) coupled with the rotary shaft (74) at its another end (74b) for actuating the clockwise and anti-clockwise rotation of said rotary shaft (74), hence enabling the rotational motion of said rotary drum (75) and said concave member (75b).

Referring to the same figures, the insertion slots (750, 752) of the first cylindrical body (75a) and the concave member (75b) are preferably comprising different sizes of insertion slots (750, 752) to accommodate or compatible with corresponding sizes of carrier tape. The leading end of carrier tape is capable of being inserted into the first arm module (7), in particular the rotary module (73) when insertion slots (750, 752) of first cylindrical body (75a) and concave member (75b) are stationed parallelly to receive the leading end of a carrier tape (C), and the leading end of the carrier tape (C) is capable of being secured or clamped in the insertion slots (750, 752) when the concave member (75b) is rotated or actuated to displace from the parallel position by the rotary cylinder (76) and the rotary union (77), hence the displacement of the insertion slot (752) of concave member (75b) from insertion slot (750) of the first cylindrical body (75a) clamping the leading end of the carrier tape (C). Once the leading end of the carrier tape (C) is clamped in the rotary module (73), the carrier tape (C) is capable of being wound on the temporary take-up reel (71) when the rotary module (73) is rotated by the motor assembly (79), and by the rotary cylinder (76) and auxiliary rotary module (77).

FIGS. 6-A and 6-B show an exemplary motor assembly (79) in perspective view and exploded view respectively, wherein said motor assembly (79) comprising at least a stepper motor (79a), at least a shaft coupling (79b) having its one end (79c) connected with the stepper motor (79a) and having its another end (79d) connected with at least a motor bearing (79e), which in turn configured to mount on the rotary shaft (74) for driving or permitting the rotary motion of the rotary shaft (74). The motor assembly (79) further comprising a clutch housing or bracket (79f) enclosing the shaft coupling (79b) for the protection of the stepper motor (79a) and shaft coupling (79b).

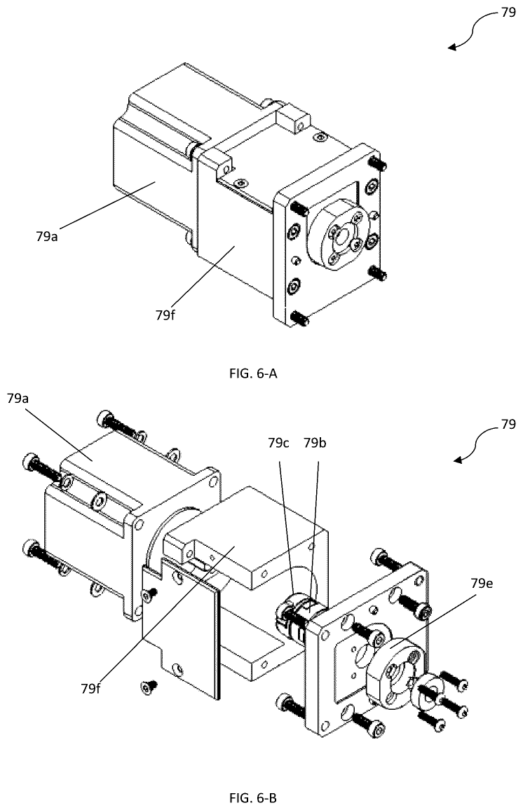

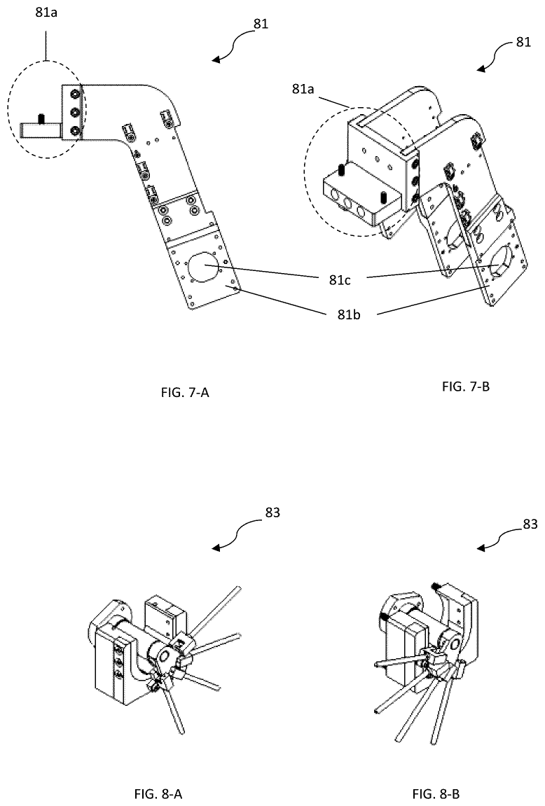

Referring back to FIGS. 1-A, 1-B, 3-B and referring to FIGS. 7-A and 7-B, the first arm module (7) further comprising at least a support arm assembly (81) having its first end (81a) capable of attaching with the tape guiding bridge module (9) or the apparatus, machine or work table of which the system (1) lies upon or the carrier tape rail track module (5), and having its second end (81b) connected with the reel plates (71a, 71b) to support and hold the first arm module (7), hence allowing the first arm module (7) to be lifted. The support arm assembly (81) comprising at least a through hole (81c) proximally to its second end (81b) for the insertion of motor assembly (79) and/or rotary shaft (73), hence supporting and holding the first arm module (7) firmly and lifting the first arm module (7).

Referring back to FIGS. 3-A and 3-B, the support arm assembly further comprising at least a pair of width adjustable members (82). The width adjustable member (82) comprising at least a first member (820) having its first end (820a) to be attached with one side of the rail track (51) and having its second end (820b) to be attached with the first reel plate (71a); at least a second member (830) having its first end (830a) to be attached with another side of the rail track (51) and having its second end (830b) to be attached with the second reel plate (71b). In this embodiment, the width widening or narrowing of the adjustable rail track (51) in respect to the size of carrier tape (C) allows the correspond width widening or narrowing first arm (810) and second arm (830), hence allowing the first and second reel plates (71a, 71b) to be adjusted accordingly and correspondingly. It should be contemplated that the insertion slots (750, 752) of the rotary drum (75) and concave member (75b) will be rotated to a tape receiving position with the right or suitable insertion slots (750, 752) that corresponds to the size of incoming tape (C).

Referring to FIGS. 8-A and 8-B, the first arm module (7) further comprising at least a positioning sensor (83) connected with the one end of the rotary shaft (73), wherein said positioning sensor (83) is preferably a photoelectric sensor used to determine or detect the distance, absence, or presence of the carrier tape. Preferably, said positioning sensor (83) acts as a feedback mechanism to controller module of the system, whereby the sensor (83) sends signal or feedback to the controller module in regards to the positioning status of the carrier tape (C) during the winding and rewinding of the carrier tape (C) into/from the first arm module (7).

Referring back to FIG. 1, the first arm module (7) further comprising at least a support mount member (85) mounting the first and second reel plates (71a, 71b) together at their circumferences, so that the reel plates (71a, 71b) are idle and stable during the winding and rewinding process of the carrier tape, hence minimizing the vibration of reel plates (71a, 71b) and enhance the smoothness of winding and rewinding process. It should be noted at this point that the temporary take-up reel (71) is idle and not rotated during the winding and rewinding of carrier tape around temporary take-up reel (71).

Referring back to FIGS. 1-A and 1-B, the tape guiding bridge module (9) of the system (1) is disposed between the carrier tape rail track module (5) and the first arm module (7), of which is configured to facilitate the automatic conveyance of carrier tape from the carrier tape rail track module (5) to the first arm module (7). The tape guiding bridge module (9) of the system (1) is the automation means of the system that performs the automatic conveyance of carrier tape (C) between first arm module (7) and carrier tape rail track module (5). This has solved the significant problem faced by the conventional inspection system whereby the manual tape attaching work is alleviated. As further shown in FIGS. 3-C and 3-D, the tape guiding bridge module (9) comprising at least a bridge (91) connecting the rail track (51) of the carrier tape rail track module (5) and the temporary take-up reel (71) of the first arm module (7), wherein the carrier tape (C) is conveyed to the bridge (91) automatically and subsequently inserted into the temporary take-up reel (71) as it moves. The bridge (91) is extendable and narrowable in width wherein the width of said bridge (91) is adjustable according to the size of carrier tape (C). It is contemplated that plurality of sensors is provided proximally to said bridge (91) to further detect the presence, size and width of the incoming carrier tape from the rail track (51), hence enabling the bridge (91) to adjust its width corresponding to the width of the carrier tape, although the size of the carrier tape (C) has already been pre-set by operators initially. The bridge (91) will firstly remain at its standby position before receiving the carrier tape, and when the incoming carrier tape (C) is detected, the bridge (91) will automatically be adjusted to the width of the carrier tape (C) for smooth conveyance of carrier tape (C) into the temporary take-up reel (71). When the leading end of the carrier tape (C) is clamped by the insertion slots (750, 752) of the first cylindrical body (75a) and concave member (75b), the bridge (91) will return back to its standby position for the smooth winding process of said carrier tape (C) on the temporary take-up reel (71) while the rotary shaft (74) is rotated by the motor assembly (79). It is pertinent to note that said temporary take-up reel (71) is not rotated during the winding process or when the rotary module (73) is rotated by the motor assembly.

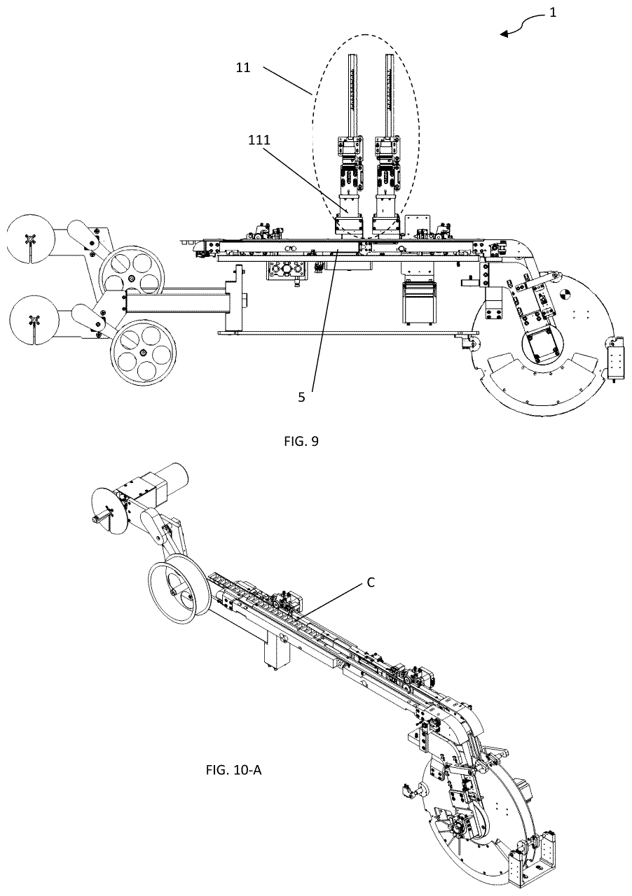

Referring to FIG. 9, the inspection module (11) of the system (1) is disposed at a position proximally to the carrier tape rail track module (5), preferably said inspection module (11) may be disposed above or below said carrier tape rail track module (5). Said inspection module (11) comprising vision or illumination system (111) such as optics, illumination, camera, light, imaging mechanisms and etc, of which is configured to inspect the carrier tape (C), the electronic components contained within the carrier tape (C), the cover tape sealing the carrier tape (C) and the seal between the cover tape and carrier tape (C). The inspection module (11) may be implemented in hardware, software or a suitable combination of hardware and software, and may be an inspection platform with programmable software systems. According to the preferred embodiment of the present invention, the inspection module (11) remains at a standby position and does not inspect the carrier tape (C) when the carrier tape (C) is being conveyed on the rail track (51) from the feeder reel module (3) to the first arm module (7). When the carrier tape (C) is wound on the temporary take-up reel (71) of the first arm module (7), the rear end of the carrier tape (C) does not wind into the temporary take-up reel (71) and remains on the rail track (51) of the carrier tape rail track module (5). The rail track (51) and the rotary shaft (74) are then rotated in the opposite direction to rewind the carrier tape (C) back to the feeder reel module (3). During the rewinding process, the inspection module (11) moves to its inspecting position and starts inspecting the carrier tape (C) starting from its rear end to detect if there is any defect. In other words, the inspection process commences on the rear end of the carrier tape (C) and only commences when the carrier tape is rewound from the first arm module (7) to the feeder reel module (3). It is pertinent to note that said temporary take-up reel (71) is not rotated during the rewinding process.

Alternatively, it is contemplated that the inspection module (11) may be configured to moves to its inspecting position to inspect the carrier tape while the carrier tape is moving from the feeder reel module (3) to the first arm module (7), hence providing double or dual inspection on the carrier tape (C).

FIGS. 10-A, 10-B, 10-C and 10-D show the exemplary operation of the system (1) as described above, in particular the conveyance of the carrier tape (C) from feeder reel module (3) to the first arm module (7) through the carrier tape rail track module (5) and tape guiding bridge module (9), and the conveyance of carrier tape from the first arm module (7) back to the feeder reel module (3) through the tape guiding bridge module (9) and carrier tape rail track module (5). Particularly, the rear end portion of the carrier tape (C) does not wind into the first arm module (7) but remains on the rail track (51) for the inspecting process by the inspection module (11) before winding back to the feeder reel module (3).

It can be deduced that the carrier tape (C) dispensed out from the supply reel or input reel (R) will be eventually packaged back into the supply reel or input reel (R) after the carrier tape (C) has been wound in the first arm module (7), rewound out from the first arm module (7) and inspected by the inspection module (11). In other words, the feeder reel module (3) acts as the collection reel module, wherein the supply reel or input reel (R) is the take-up reel or packaging reel.

In another embodiment of the present invention, plurality of the system (1) of may be provided to enhance or increase the productivity rate. As shown in FIGS. 10-D and 11, dual system (1) may be provided within an apparatus to enhance the productivity rate. It is contemplated that plurality of the system (1) can be provided within an apparatus or cabinet (13) of which the systems (1) lie upon. In this embodiment, it is contemplated that any number of inspection module (11) may be used, wherein the inspection module (11) may be shared to take turn to inspect the carrier tape of each system (1). When the inspection module (11) is inspecting the carrier tape of the first system (1ₙ), the second system (1ₙ₊₁) is sequenced to convey the carrier tape into the first arm module of the second system (1ₙ₊₁), and vice versa. When the first system (1) completes the inspection, the inspection module (11) is coordinated to move to the second system (1ₙ₊₁) to carry out its inspection. Alternatively, each system (1) may have their own inspection module (11).

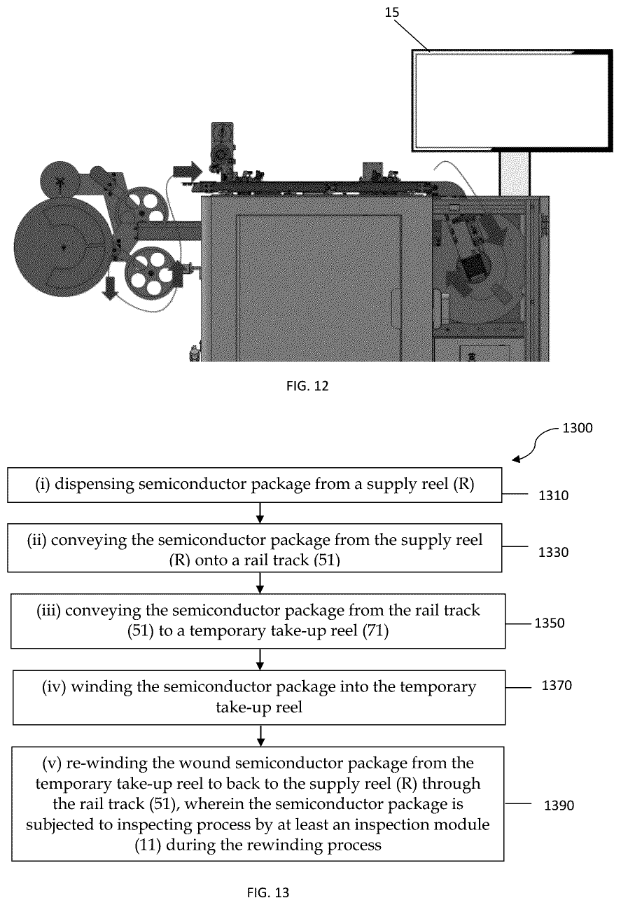

Referring now to FIG. 12, it should be understood that the system (1) of the present invention may comprising at least a controller module (15) which is mounted on or connected to said system (1) for the use of operators to operate or control said system (1) such as pre-setting the requirements like, inputting the size of carrier tape (C), presetting the width of the rail track (51) to corresponds with the size of carrier tape (C) or etc. Said controller module (15) comprising at least an input device such as user interface device, monitor, keyboard for the operators to operate or manipulate the system (1). Said controller module (15) is electrically or operatively coupled to the system (1) to perform its functionality. It is contemplated that the system (1) may further comprising at least an electrical panel unit (not shown) comprising electrical modules or components configured to provide, supply, control or regulate electricity to each part of said system (1), whereby it acts as an electrical supply system to said system (1).

In another embodiment of the present invention, the system (1) according to the present invention may further comprising at least a labelling or marking module (not shown) disposed proximally to said inspection module (11) to label or mark the defective electronic components, the defective sealing line, or defective pockets of carrier tape (C) before the carrier tape (C) is re-winded back to the feeder reel module (3).

Referring to FIG. 13, there is shown an exemplary method (1300) for conveying and inspecting semiconductor package-according to the present invention. The semiconductor package is a carrier tape (C) containing at least an electronic component or is a carrier tape (C) does not contain electronic component. The method (1300) for conveying and inspecting semiconductor package, in particular carrier tape (C), comprising the step of (i) dispensing semiconductor package, in particular carrier tape (C) from a supply reel (R) (1310); the step of (ii) conveying the semiconductor package, in particular carrier tape (C) from the supply reel (R) onto a rail track (51) (1330); the step of (iii) conveying the semiconductor package, in particular carrier tape (C) from the rail track (51) to a temporary take-up reel (71) (1350); the step of (iv) winding the semiconductor package, in particular carrier tape (C) into the temporary take-up reel (71) (1370), wherein the rear end portion of semiconductor package, in particular the carrier tape (C) does not wind into the temporary take-up reel (71) and remains on the rail track (51); and the step of (v) re-winding the wound carrier tape (C) from the temporary take-up reel (71) to back to the supply reel (R) through the rail track (51) (1390). The semiconductor package, in particular carrier tape (C) is subjected to inspecting process by at least an inspection module (11) during step (iv) (1390) when the rear end of the semiconductor package, in particular carrier tape (C) is rewound back to the supply reel (R).

Preferably, the winding process in said step (iii) and re-winding process in said step (v) are performed automatically using an automation means. Said automation means is the tape guiding bridge module (9), of which is configured to facilitate the automatic conveyance of semiconductor package, in particular carrier tape (C).

If the carrier tape (C) contains electronic components, the inspection area of the inspecting process by at least an inspection module (11) includes but not limited to inspection of the carrier tape (C), the cover tape sealing the carrier tape (C), the electronic components that are sealed within the carrier tape (C), the sealing between the cover tape and carrier tape (C) or the packaging state of the carrier tape (C), if the carrier tape (C) does not contain electronic component.

If the carrier tape (C) does not contain electronic components, the inspection area of the inspecting process by at least an inspection module (11) includes but not limited to inspection of the carrier tape (C), the cover tape sealing the carrier tape (C), the sealing between the cover tape and carrier tape (C) or the packaging state of the carrier tape (C), if the carrier tape (C) does not contain electronic component.

While the present invention has been shown and described herein in what are considered to be the preferred embodiments thereof, illustrating the results and advantages over the prior art obtained through the present invention, the invention is not limited to those specific embodiments. Thus, the forms of the invention shown and described herein are to be taken as illustrative only and other embodiments may be selected without departing from the scope of the present invention, as set forth in the claims appended hereto. The scope of the invention encompasses numerous alternatives, modifications and the equivalents. Of necessity, there are many alternative ways of configuring and implementing the invention to suit particular installations and environments while providing biological outcomes of differing design.

1. A system for conveying and inspecting semiconductor package comprising:
at least a feeder reel module located on one side of the system for mounting at least a supply reel wound with semiconductor package;
at least a carrier tape rail track module for receiving the semiconductor package dispensed from the feeder reel module and conveying the semiconductor package;
at least an inspection module disposed at a position proximally to the carrier tape rail track module;
characterized in that
said system further comprising at least a first arm module located on another side of the system for winding the semiconductor package conveyed from the carrier tape rail track module and rewinding the wound semiconductor package to the inspection module for inspection before the inspected semiconductor package winds back into feeder reel module, wherein said winding and rewinding process are performed automatically using an automation means.

2. The system for conveying and inspecting semiconductor package as claimed in claim 1, wherein said semiconductor package is a carrier tape containing at least an electronic component or is a carrier tape does not contain electronic component.

3. The system for conveying and inspecting semiconductor package as claimed in claim 2, further comprising at least a tape guiding bridge module disposed between the carrier tape rail track module and the first arm module for automatically guiding the carrier tape from the carrier tape rail track module into the first arm module.

4. The system for conveying and inspecting semiconductor package as claimed in claim 2, wherein said first arm module comprising a temporary take-up reel comprising at least a first reel plate comprising a through hole; a second reel plate comprising a through hole facing the first reel plate substantially parallelly; at least a rotary module disposed between the first and second reel plates, wherein said rotary module comprising at least a rotary shaft having its one end coupled with at least a rotary drum, and having its another end coupled with at least a motor assembly for actuating the clockwise and anti-clockwise rotation of said rotary shaft.

5. The system for conveying and inspecting semiconductor package as claimed in claim 4, wherein said rotary drum comprising a first cylindrical body comprising at least an insertion slot at its surface; at least a concave member comprising at least an insertion slot wherein said concave member is positioned beneath said first cylindrical body and is formed with the same radius of curvature with said first cylindrical body.

6. The system for conveying and inspecting semiconductor package as claimed in claim 5, wherein the leading end of carrier tape is capable of being inserted into the rotary drum when insertion slots first cylindrical body and concave member are stationed parallelly to receive the leading end of a carrier tape; the leading end of the carrier tape is capable of being secured or clamped in the insertion slots when the concave member is rotated or actuated to displace from the parallel position by a rotary cylinder hence the displacement of the insertion slot of concave member from insertion slot of the first cylindrical body clamping the leading end of the carrier tape; and the carrier tape is capable of being wound around said temporary take-up reel when the rotary module is being rotated.

7. The system for conveying and inspecting semiconductor package as claimed in claim 4, wherein said temporary take-up reel is not rotated when the rotary module is rotated by the motor assembly.

8. The system for conveying and inspecting semiconductor package as claimed in claim 3, wherein said tape guiding bridge module comprising at least an adjustable bridge, of which is automatically extendable and narrowable in width to correspond with different sizes of carrier tape.

9. The system for conveying and inspecting semiconductor package as claimed in claim 2, wherein said carrier tape rail track module comprising at least an adjustable rail track, wherein the width of the rail track is adjusted automatically and correspondingly to the size of carrier tape.

10. The system for conveying and inspecting semiconductor package as claimed in claim 2, wherein the inspection area of the carrier tape includes but not limited to the inspection on the carrier tape, the electronic components that are sealed within the carrier tape, the cover tape sealing the carrier tape, the sealing between the cover tape and carrier tape or the packaging state of the carrier tape, if the carrier tape contains electronic component.

11. The system for conveying and inspecting semiconductor package as claimed in claim 2, wherein the inspection area of the carrier tape includes but not limited to the inspection on the carrier tape, the cover tape sealing the carrier tape, the sealing between the cover tape and carrier tape or the packaging state of the carrier tape, if the carrier tape does not contain electronic component.

12. A method for conveying and inspecting semiconductor package comprising the steps of:
(i) dispensing semiconductor package from a supply reel;
(ii) conveying the semiconductor package from the supply reel onto a rail track;
(iii) conveying the semiconductor package from the rail track to a temporary take-up reel;
characterized in that the method further comprising the step of
(iv) winding the semiconductor package into the temporary take-up reel;
(v) re-winding the wound semiconductor package from the temporary take-up reek to back to the supply reel through the rail track; wherein the semiconductor package is subjected to inspecting process by at least an inspection module during the rewinding process.

13. The method for conveying and inspecting semiconductor package as claimed in claimed 12, wherein the winding process in said step (iii) and re-winding process in said step (v) are performed automatically.

14. The method for conveying and inspecting semiconductor package as claimed in claim 12, wherein the semiconductor package is a carrier tape containing at least an electronic component or is a carrier tape does not contain electronic component.

15. The method for conveying and inspecting semiconductor package as claimed in claim 14, wherein the inspecting process by at least an inspection module includes inspecting the carrier tape, the electronic components that are sealed within the carrier tape, the cover tape sealing the carrier tape, the sealing between the cover tape and carrier tape or the packaging state of the carrier tape, if the carrier tape contains electronic component.

16. The method for conveying and inspecting semiconductor package as claimed in claim 14, wherein the inspecting process by at least an inspection module includes inspecting the carrier tape, the cover tape sealing the carrier tape, the sealing between the cover tape and carrier tape or the packaging state of the carrier tape, if the carrier tape does not contain electronic component.
